(19) United States
(12) Patent Application Publication
(10) Pub. No.: US 2020/0291542 A1
(43) Pub. Date: Sep. 17, 2020

(54) APPARATUS AND METHOD OF CORRECTING MAGNETIC FIELD OF HIGH-TEMPERATURE CHAMBER

(71) Applicant: WOONGJIN ENERGY CO., LTD., Daejeon (KR)

(72) Inventors: Sung Sun BAIK, Gyeongsangbuk-do (KR); Jae Chang PARK, Daejeon (KR); Jong Jin SHIN, Chungcheongnam-do (KR)

(73) Assignee: WOONGJIN ENERGY CO., LTD., Daejeon (KR)

(21) Appl. No.: 16/300,468

(22) PCT Filed: Dec. 6, 2017
(86) PCT No.: PCT/KR2017/014179

§ 371 Date: Nov. 9, 2018

(30) Foreign Application Priority Data
Dec. 5, 2017 (KR) 10-2017-0166141

(51) Int. Cl. C30B 30/04; G01R 33/00; C30B 15/14

(52) U.S. Cl. CPC C30B 30/04; C30B 15/14; G01R 33/0076

(57) ABSTRACT

Provided is an apparatus and method of correcting a magnetic field of a high-temperature chamber. The apparatus includes a high-temperature magnetic field sensor unit for being inserted into a high-temperature chamber in a high-temperature environment and detecting a magnetic field generated by a magnet heater, a magnetic field comparing unit for comparing a result of detection of the high-temperature magnetic field sensor unit with a target magnetic field and obtaining a difference between the detected magnetic field and the target magnetic field, and a current parameter controller for correcting current parameters according to a result of comparison of the magnetic field comparing unit and controlling the magnet heater.

### FIELD OF THE DISCLOSURE

The present invention relates to an apparatus and method of correcting a magnetic field of a high-temperature chamber, and more particularly, to an apparatus and method of correcting a magnetic field of a high-temperature chamber with which a magnetic field within a chamber for providing a high-temperature environment, such as an ingot growing apparatus, can be detected and corrected.

### DESCRIPTION OF RELATED ART

Generally, a monocrystalline silicon ingot for solar use is grown using a high-temperature chamber, and a wafer made of the monocrystalline silicon ingot for solar use includes more oxygen atoms than those of a wafer made of a polycrystalline ingot. This is because more oxygen atoms are introduced into a molten liquid from a quartz crucible.

A high oxygen concentration in the ingot is coupled to boron (B), which is a master dopant, and causes a light induced degradation (LID) phenomena that decrease efficiency of a solar cell.

In order to solve this problem, Korean Patent Registration No. 10-0830047 (registered on May 8, 2008, entitled “Method of Manufacturing Semiconductor Single Crystal with which oxygen concentration control can be performed by convection distribution control, Apparatus therefor and Semiconductor Single Crystal Ingot) discloses a method of controlling an oxygen concentration by minimizing natural convection of a molten liquid and maximizing forced convection using a magnetic field.

Recently, a magnet heater, in which a heater for maintaining a high-temperature environment and a magnetic field generating unit for controlling convection of the molten liquid are integrated with each other so as to reduce manufacturing costs, has been used.

However, the magnet heater is damaged by various oxides that are formed within a high-temperature chamber, as illustrated in FIG. 1, and the thickness of the magnet heater is reduced by the damage such that a resistance value of the magnet heater is changed.

A change in the resistance value of the magnet heater changes a magnetic field output value of the magnet heater such that it is difficult to control an oxygen concentration as described above.

In this case, it is possible to measure the magnetic field and to compensate for a change in the magnetic field. However, a sensor for measuring the magnetic field may be damaged in the high-temperature environment and thus cannot measure the magnetic field and thus the sensor for measuring the magnetic field should measure the magnetic field after the high-temperature chamber is cooled at a particular temperature or less.

However, the magnet heater generates the magnetic field and heat simultaneously. The intensity or shape of the magnetic field detected at the particular temperature or less cannot be applied to compensate.

Thus, even when a relatively low cost magnet heater is used, periodic replacement of the magnet heater is required. This frequent replacement of the magnet heater causes an increase in cost and a reduction in productivity due to stoppage of a process.

### SUMMARY OF THE INVENTION

The present invention is directed to providing an apparatus and method of correcting a magnetic field of a high-temperature chamber with which a magnetic field can be measured even in a high-temperature environment of the high-temperature chamber, and the magnetic field due to damage to a magnet heater can be compensated for.

One aspect of the present invention provides an apparatus for correcting a magnetic field of a high-temperature chamber, the apparatus including a high-temperature magnetic field sensor unit inserted into a high-temperature chamber in a high-temperature environment and configured to detect a magnetic field generated by a magnet heater, a magnetic field comparing unit for comparing a result of detection of the high-temperature magnetic field sensor unit with a target magnetic field and for obtaining a difference between the detected magnetic field and the target magnetic field, and a current parameter controller for correcting current parameters according to a result of comparison of the magnetic field comparing unit and controlling the magnet heater.

The high-temperature magnetic field sensor unit may include a magnetic field sensor for detecting a magnetic field, a protection tube configured to accommodate the high-temperature magnetic field sensor unit thereinside so that the magnetic field sensor is not exposed to the outside, and an insulating material for encompassing an outer surface of the protection tube.

The protection tube may include a graphite or quartz tube.

A protrusion may be formed on a top end of the protection tube and may be fixed to a seed-fixing unit for fixing seed so as to form an ingot.

The insulating material may include a carbon fiber or rigid felt.

The insulating material may have a thickness of 100 to 150 mm that protrudes from a surface to sides of the protection tube.

Another aspect of the present invention provides a method of correcting a magnetic field of a high-temperature chamber, the method including a) detecting a magnetic field within a high-temperature chamber at a processing temperature using a high-temperature magnetic field sensor unit, b) comparing the detected magnetic field with a target magnetic field, and c) controlling the magnet heater to generate a magnetic field within the high-temperature chamber by adjusting current parameters according to the result of comparison.

The high-temperature chamber may be a chamber for manufacturing an ingot, and the high-temperature magnetic field sensor unit may be inserted into the high-temperature chamber by a lifting cable for lifting the ingot.

After performing c), the method may return to a), and c) may be performed until the detected magnetic field resulting from the comparing in b) and the target magnetic field coincide with each other.

In an apparatus and method of correcting a magnetic field of a high-temperature chamber according to the present invention, the magnetic field can be detected in the same temperature condition as a process state of the high-temperature chamber, the detected magnetic field can be compared with an initially-set magnetic field, and a magnet heater is controlled with current parameters corresponding to a reduction in the magnetic field so as to maintain a target magnetic field so that the life-span of the magnet heater can be extended and costs can be reduced.

### BRIEF DESCRIPTION OF THE DRAWINGS

FIG. 1 is a photo showing a damaged magnet heater according to the related art.

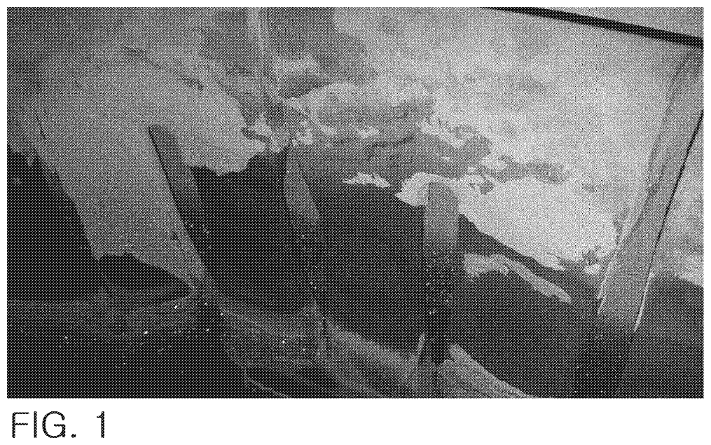

FIG. 2 is a view of a configuration of an apparatus for correcting a magnetic field of a high-temperature chamber according to an example embodiment of the present invention.

FIG. 3 is a cross-sectional view of a configuration of a high-temperature magnetic field sensing unit according to an embodiment of the present invention.

- Explanations of reference numerals -

| | |
|---|---|
| 10: high-temperature chamber | 11: magnet heater |
| 12: crucible | 13: lifting cable |
| 20: high-temperature magnetic field | 21: protection tube |
| sensor unit | |
| 22: magnetic field sensor | 23: insulating material |
| 30: magnetic field comparing unit | 40: current parameter controller |

### DETAILED DESCRIPTION OF THE INVENTION

Hereinafter, an apparatus and method of correcting a magnetic field of a high-temperature chamber according to example embodiments of the present invention will be described more fully with reference to the accompanying drawings.

The example embodiments will be provided to those skilled in the art so as to more completely describe the invention, and the following embodiments may be embodied in many different forms and should not be construed as being limited to the example embodiments set forth herein. Rather, these embodiments are provided to those skilled in the art so as to more faithfully and completely describe the invention and to completely convey the spirit of the invention.

The terminology used herein is for the purpose of describing particular embodiments only and is not intended to be limiting to the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, components, and/or groups thereof but do not preclude the presence or addition of one or more other features, regions, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiment.

Hereinafter, example embodiments of the present invention will be described with reference to accompanying drawings schematically illustrating the embodiments. In the drawings, for example, illustrated shapes may be deformed according to fabrication technology and/or tolerances. Therefore, the example embodiments of the present invention are not limited to certain shapes illustrated in the present specification and may include modifications of shapes caused in fabrication processes.

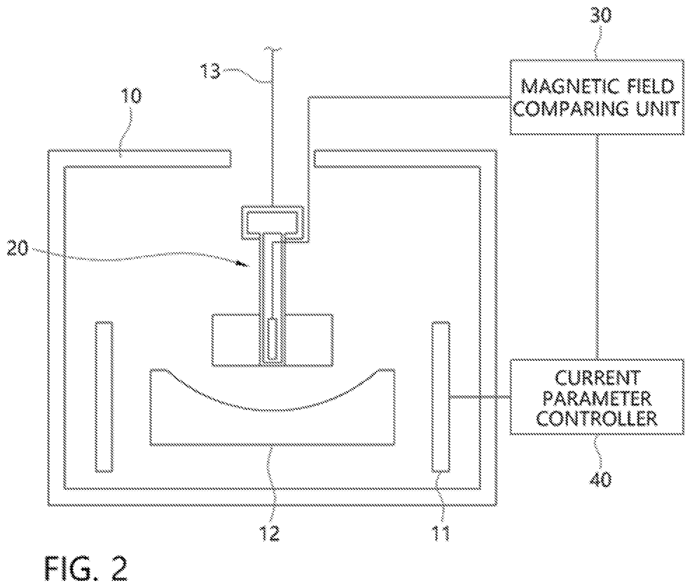

FIG. 2 is a view of a configuration of an apparatus for correcting a magnetic field of a high-temperature chamber according to an example embodiment of the present invention.

Referring to FIG. 2, the apparatus for correcting a magnetic field of a high-temperature chamber according to an example embodiment of the present invention includes a magnet heater 11 for generating the magnetic field and heating an inside of a chamber 10, a crucible 12 for maintaining an accommodated molten liquid to be molten by heat of the magnet heater 11, a lifting cable 13 for growing an ingot from the molten liquid of the crucible 12 using coupled seed, a high-temperature magnetic field sensor unit 20 mounted on the lifting cable 13 and configured to detect the magnetic field generated by the magnet heater 11 in a high-temperature environment, a magnetic field comparing unit 30 for receiving a magnetic field value detected by the high-temperature magnetic field sensor unit 20 and comparing the detected magnetic field value with a target magnetic field value, and a current parameter controller 40 for controlling magnetic field parameters of the magnet heater 11 according to the result of comparison of the magnetic field comparing unit 30 and correcting the magnetic field generated by the magnet heater 11 with a normal magnetic field.

Hereinafter, the configuration and operation of the apparatus for correcting the magnetic field of the high-temperature chamber having the above configuration according to an example embodiment of the present invention will be described in more detail. First, the magnet heater 11 is positioned to encompass the crucible 10 at sides of the crucible 10, which accommodates the molten liquid, and the surface of the magnet heater 11 becomes damaged by oxides that are generated by repeating a process of growing the ingot from the molten liquid of the crucible 10 using the lifting cable 13.

The magnet heater 11 having a reduced thickness due to the damaged surface has a varying resistance value, and even when the magnet heater 11 is controlled by the same current parameters, the magnetic field of the magnet heater 11 is changed due to a change in the resistance value.

Thus, in the present invention, the high-temperature magnetic field sensor unit 20 is mounted on the lifting cable 13 periodically after a process is performed a predetermined number of times so that the magnetic field within the high-temperature chamber 10 may be detected and a change in the magnetic field may be checked.

The high-temperature magnetic field sensor unit 20 may detect the magnetic field in the same condition as that of a real process of growing an ingot.

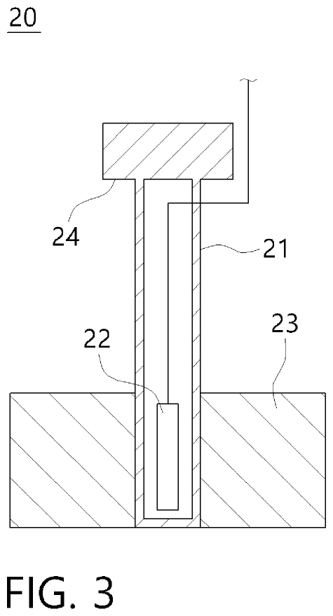

FIG. 3 is a cross-sectional view of a configuration of the high-temperature magnetic field sensor unit 20.

Referring to FIG. 3, the high-temperature magnetic field sensor unit 20 according to the present invention includes a magnetic field sensor 22 for detecting a magnetic field, a protection tube 21 configured to accommodate the high-temperature magnetic field sensor unit 20 thereinside so that the magnetic field sensor 22 is not exposed to the outside, and an insulating material 23 that encompasses an outer surface of the protection tube 21.

The high-temperature magnetic field sensor unit 20 is capable of preventing the magnetic field sensor 22 from being thermally damaged in a high-temperature condition in which the molten liquid is maintained to be molten, and the protection tube 21 may include a graphite or quartz tube.

Also, in order to measure the magnetic field, no other equipment is additionally installed at the high-temperature chamber 10, and in order to move the high-temperature magnetic field sensor unit 20 into the high-temperature chamber 10 using the above-described lifting cable 13, a protrusion 24 is formed on a top end of the protection tube 21.

The insulating material 23 may be emplaced to cover the whole of the outer surface of the protection tube 21 but may be installed to selectively cover only the outer surface of the protection tube 21 of a region in which the magnetic field sensor 22 is located, in consideration of cost and weight.

A material used for the insulating material 23 may be a carbon fiber or a rigid felt that is a combination of a graphite fiber and the carbon fiber.

The thickness of the insulating material 23 that protrudes from the outer surface to sides of the protection tube 21 may be 100 to 150 mm.

The high-temperature magnetic field sensor unit 20 having the above configuration is mounted on a seed-coupled portion of the lifting cable 13. As described above, the protrusion 24 is mounted on the seed-coupled portion such that the high-temperature magnetic field sensor unit 20 may be stably inserted into a particular position of the high-temperature chamber 10 without additionally installing other equipment, and when measurement is completed, the high-temperature magnetic field sensor unit 20 may be lifted and removed.

The high-temperature magnetic field sensor unit 20 is moved to a position corresponding to the crucible 12 by the lifting cable 13. In this case, the magnet heater 11 may generate a magnetic field according to predetermined current parameters and generate heat required for an ingot growing process.

That is, the same atmosphere as that of the ingot growing process is provided. In this state, the high-temperature magnetic field sensor unit 20 is moved to an upper portion of the crucible 12. In this case, the magnetic field sensor 22, which is insulated by the insulating material 23 and to which thermal damage is prevented, detects the magnetic field at the crucible 12, exactly, at a position corresponding to the molten liquid.

The detected magnetic field is input into the magnetic field comparing unit 30 and is compared with an initial target magnetic field. The magnetic field comparing unit 30 compares the target magnetic field with the magnetic field detected by the high-temperature magnetic field sensor unit 20.

Next, the current parameter controller 40, into which the result of comparison of the magnetic field comparing unit 30 is input, generates current parameters to correct a difference between the target magnetic field and the currently-detected magnetic field and controls the magnet heater 11 using the generated current parameters, thereby correcting a change of the magnetic field caused by a change of resistances.

In this case, the high-temperature magnetic field sensor unit 20 re-detects the corrected magnetic field and provides the re-detected magnetic field to the magnetic field comparing unit 30, and the current parameter controller 40 controls the magnet heater 11 by correcting the current parameters again using the result of comparison by the magnetic field comparing unit 30.

By repeating this procedure, the currently-detected magnetic field can be completely corrected to the target magnetic field.

In this way, according to the present invention, the magnetic field, which is changed by the magnet heater 11 being damaged by oxides generated during a process, and by a change of resistances, can be compensated for such that the life-span of the magnet heater 11 can be expanded.

While the invention has been shown and described with reference to certain exemplary embodiments thereof, it will be understood by those skilled in the art that various changes in form and details may be made therein without departing from the spirit and scope of the invention as defined by the appended claims.

According to the present invention, when a magnet heater is used in a high-temperature chamber, such as an ingot growing apparatus, a varying magnetic field caused by damage to the magnet heater can be detected, and the detected magnetic field can be corrected. Therefore, there is industrial applicability.

1. An apparatus for correcting a magnetic field of a high-temperature chamber, the apparatus comprising:
a high-temperature magnetic field sensor unit mounted on a lifting cable configured to grow an ingot from molten liquid, the high temperature magnetic field sensor unit configured to detect a magnetic field generated by a magnet heater, wherein the high-temperature magnetic field sensor unit comprises:
a magnetic field sensor;
a protection tube formed of a graphite or quartz material configured to accommodate the magnetic field sensor therein; and
an insulating material configured to encompass a part of an outer surface of the protection tube in which the magnetic field sensor is located in consideration of cost and weight, comprising an insulating carbon fiber or rigid felt material, and having a thickness of 100 to 150 mm that protrudes from a surface to sides of the protection tube;
a magnetic field comparing unit configured to compare a result of detection of the high-temperature magnetic field sensor unit with a target magnetic field and obtain a difference between the detected magnetic field and the target magnetic field; and
a current parameter controller configured to correct current parameters according to a result of comparison of the magnetic field comparing unit and control the magnet heater using the corrected current parameter, so that a change in magnetic field due to damage to the magnet heater can be compensated for, wherein a protrusion is formed on a top end of the protection tube, and is fixed to a seed-fixing unit for fixing seed to form an ingot, so that the high-temperature magnetic field sensor unit including the protection tube is stably inserted into the ingot growing apparatus, and is removed when measurement is completed.

2-9. (canceled)
